(19) United States
(12) Patent Application Publication
(10) Pub. No.: US 2025/0149472 A1
(43) Pub. Date: May 8, 2025

(54) HIGH-FREQUENCY CIRCUIT COMPONENT

(71) Applicant: Murata Manufacturing Co., Ltd., Kyoto-fu (JP)

(72) Inventors: Hisatoshi KAWABATA, Nagaokakyo-shi (JP); Mari SAJI, Nagaokakyo-shi (JP)

(73) Assignee: Murata Manufacturing Co., Ltd., Kyoto-fu (JP)

(21) Appl. No.: 18/921,192

(22) Filed: Oct. 21, 2024

(30) Foreign Application Priority Data
Nov. 7, 2023 (JP) 2023-190028

(51) Int. Cl. H01L 23/66; H01L 23/32; H01L 23/528; H01L 23/552; H01L 25/16

(52) U.S. Cl. CPC H01L 23/66; H01L 23/32; H01L 23/5283; H01L 23/5286; H01L 23/552; H01L 25/16; H01L 2223/6655; H01L 2223/6677

(57) ABSTRACT

A first chip includes a first insulating layer, a first device layer laminated on the first insulating layer, a first multilayer wiring layer laminated on the first device layer, and a first anchor. A high-frequency circuit is in the first chip. A second chip includes a substrate, a second multilayer wiring layer on the substrate, and a second anchor. A control circuit that controls the high-frequency circuit is in the second chip. The first anchor is embedded in the first device layer and the first insulating layer, and exposed from a surface of the first insulating layer. The second anchor is embedded in the second multilayer wiring layer, and exposed from a surface of the second multilayer wiring layer. The first and second anchors are formed from an identical metal material.

### CROSS-REFERENCE TO RELATED APPLICATION

This application claims benefit of priority to Japanese Patent Application No. 2023-190028, filed Nov. 7, 2023, the entire content of which is incorporated herein by reference.

### BACKGROUND

### Technical Field

The present disclosure relates to a high-frequency circuit component.

### Background Art

As known, a high-frequency module includes a dielectric multilayer substrate on which a high-frequency switch element and a decoder element are mounted as described, for example, in Japanese Unexamined Patent Application Publication No. 2006-203470. This high-frequency module is mounted on, for example, a main board of a radio communication device such as a mobile terminal. A transmission signal from a transmitter/receiver system is transmitted to an antenna terminal through the high-frequency switch, and a reception signal input from the antenna terminal is transmitted to the transmitter/receiver system through the high-frequency switch.

### SUMMARY

In addition to the high-frequency module including components such as a high-frequency switch, the main board of a radio communication device receives components such as a power amplifier that amplifies power of a transmission signal, a low-noise amplifier that amplifies a reception signal, and a control circuit that controls the power amplifier and the low-noise amplifier. The main board thus needs to have a region in the mount surface to receive these circuit components. For size reduction of the radio communication device, a size reduction of the high-frequency circuit component is desired.

To improve the operation speed of a transistor included in, for example, the low-noise amplifier or the power amplifier, a semiconductor-on-insulator (SOI) substrate may be used instead of a bulk silicon substrate. When the operation frequency of a high-frequency circuit becomes higher, the nonlinearity of the parasitic capacitance between the transistor disposed on the SOI layer and the silicon substrate underlying the embedded oxide film becomes more pronounced, and the effect of improving the high-frequency characteristics is reduced.

The present disclosure aims to provide a high-frequency circuit component that has a reduced size, and that can maintain high-frequency characteristics.

An aspect of the present disclosure provides a high-frequency circuit component including a first chip that includes a first insulating layer, a first device layer laminated on the first insulating layer, a first multilayer wiring layer laminated on the first device layer, and a first anchor to form a high-frequency circuit; and a second chip that includes a substrate, a second multilayer wiring layer disposed on the substrate, and a second anchor to form a control circuit that controls the high-frequency circuit. The first anchor is embedded in the first device layer and the first insulating layer, and exposed from a surface of the first insulating layer. The second anchor is embedded in the second multilayer wiring layer, and exposed from a surface of the second multilayer wiring layer. The first anchor and the second anchor are formed from an identical metal material, and a portion of the first anchor exposed from the surface of the first insulating layer and a portion of the second anchor exposed from the surface of the second multilayer wiring layer are connected to each other.

The first chip is laminated on the second chip. Thus, compared to a structure where the first chip and the second chip are separately mounted on a mounting board, the high-frequency circuit component has a reduced size. The first anchor exposed from the surface of the first insulating layer in the first chip is connected to the second anchor in the second chip, and thus a support board that individually and mechanically supports the first chip is not needed. In a structure where the first chip includes a support board made of silicon or another material, the high-frequency characteristics are reduced with the effect of the parasitic capacitance between the support board and the high-frequency circuit of the first chip. However, the structure according to the aspect of the present disclosure does not need the support board, and thus can maintain the high-frequency characteristics.

### BRIEF DESCRIPTION OF THE DRAWINGS

FIG. 1A is a schematic cross-sectional view of a high-frequency circuit component according to a first embodiment, FIG. 1B is a diagram of an arrangement of a first anchor and a second anchor in a plan view, FIG. 1C is a schematic cross-sectional view of an example of a connection portion between the first anchor and the second anchor, and FIG. 1D is a schematic cross-sectional view of another example of a connection portion between the first anchor and the second anchor;

FIG. 2A is a block diagram of the high-frequency circuit component according to the first embodiment, and FIG. 2B is a diagram of a positional relationship between the high-frequency circuit, an input/output buffer circuit, a digital logic circuit, and an analog control circuit, when viewed in a plan;

FIG. 3A, FIG. 3B, and FIG. 3C are schematic cross-sectional views of the high-frequency circuit component according to the first embodiment in manufacturing process;

FIG. 4A and FIG. 4B are schematic cross-sectional views of the high-frequency circuit component according to the first embodiment in manufacturing process;

FIG. 5 is a schematic cross-sectional view of a high-frequency circuit component according to a second embodiment;

FIG. 6A is a diagram of a positional relationship between a first chip, a second chip, a first anchor, and a second anchor in a high-frequency circuit component according to a third embodiment in a plan view, and FIG. 6B is a schematic cross-sectional view of the first chip;

FIG. 7 is a schematic cross-sectional view of a high-frequency circuit component according to a fourth embodiment;

FIG. 8 is a schematic cross-sectional view of a high-frequency circuit component according to a fifth embodiment;

FIG. 9 is a schematic cross-sectional view of a high-frequency circuit component according to a sixth embodiment;

FIG. 10 is a schematic cross-sectional view of a high-frequency circuit component according to a seventh embodiment; and

FIG. 11A is a schematic cross-sectional view of a high-frequency circuit component according to an eighth embodiment, and FIG. 11B is a diagram of a positional relationship among various components in a high-frequency circuit component in a plan view.

### DETAILED DESCRIPTION

### First Embodiment

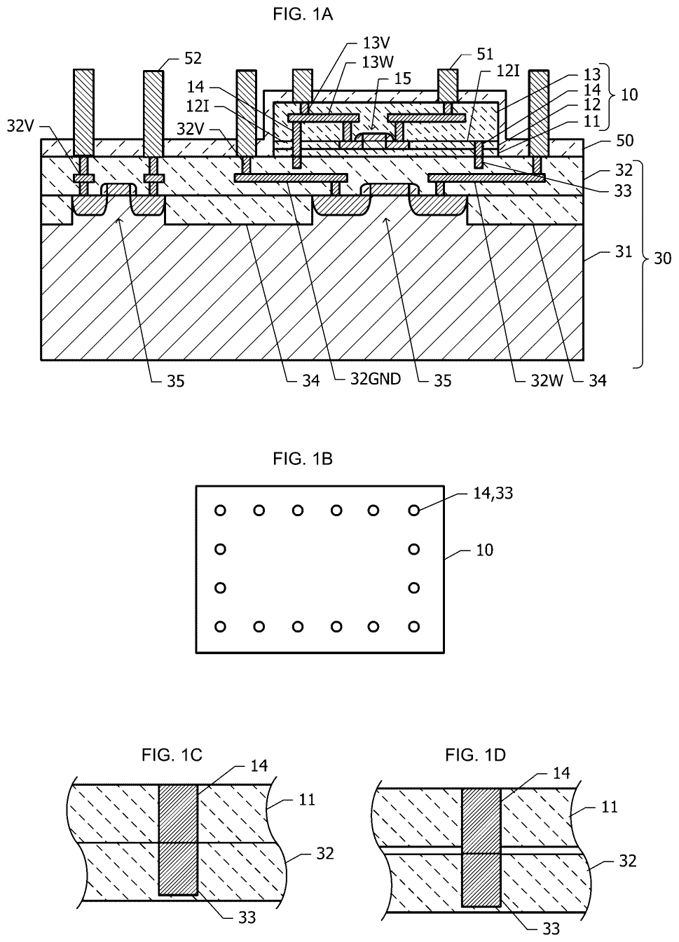

With reference to FIG. 1A to FIG. 4B, a high-frequency circuit component according to a first embodiment is described.

FIG. 1A is a schematic cross-sectional view of a high-frequency circuit component according to a first embodiment. The high-frequency circuit component according to the first embodiment includes a first chip 10 and a second chip 30. In FIG. 1A, for example, the number of various components included in the high-frequency circuit component, such as transistors, wires, vias, or bumps, the size of the components, and the positional relationship between the components may be different from the actual number, size, or positional relationship.

The first chip 10 includes a first insulating layer 11, a first device layer 12 laminated on the first insulating layer 11, a first multilayer wiring layer 13 laminated on the first device layer 12, and multiple first anchors 14. The first insulating layer 11 and the first device layer 12 correspond to an embedded oxide film and a silicon-on-insulator (SOI) layer of an SOI substrate. Specifically, a laminated structure of the first insulating layer 11 and the first device layer 12 can be obtained by removing a silicon support board of the SOI substrate.

Element isolation regions 12I are formed at portions of the first device layer 12 to define active regions formed from a semiconductor (such as silicon) surrounded by the element isolation regions 12I. A source region, a drain region, and a body region are formed in the active regions of the first device layer 12, and a gate electrode is disposed on the body region. The source region, the drain region, the body region, and the gate electrode form a transistor 15. The transistor 15 is, for example, a metal oxide semiconductor field-effect transistor (MOSFET).

In the first multilayer wiring layer 13, multiple wires 13W and multiple vias 13V are disposed. The multiple transistors 15 and the wires 13W and the vias 13V in the first multilayer wiring layer 13 form a high-frequency circuit. The first anchors 14 have a prism shape, and are formed from metal. The first anchors 14 are embedded in the element isolation region 12I in the first device layer 12 and the first insulating layer 11, and have first ends exposed from the surface (the surface facing away from the first device layer 12) of the first insulating layer 11. At least one of the multiple first anchors 14 has a second end reaching the wires 13W, and the other first anchors 14 have second ends reaching the interface between the element isolation region 12I and the first insulating layer 11.

The second chip 30 includes a substrate 31, a second multilayer wiring layer 32 laminated on the substrate 31, and second anchors 33 embedded in the second multilayer wiring layer 32. The substrate 31 is, for example, a semiconductor substrate (for example, a silicon substrate). Element isolation regions 34 formed on a top layer portion of the substrate 31 define multiple active regions. Multiple transistors 35 are disposed on the multiple active regions and in the active region. The transistors 35 are, for example, MOSFETs. In the second multilayer wiring layer 32, multiple wires 32W, multiple vias 32V, and the second anchors 33 are disposed. A subset of the multiple wires 32W serves as a ground wire 32GND.

The multiple transistors 35, the multiple wires 32W, and the multiple vias 32V form a control circuit that controls the high-frequency circuit disposed on the first chip 10. The second anchors 33 have a prism shape, and are formed from the same metal material as the first anchors 14. The first anchors 14 and the second anchors 33 may be formed from an alloy containing multiple metallic elements or an alloy containing at least one metallic element and at least one non-metallic element. In this case, the structure where the first anchors 14 and the second anchors 33 are formed from “the same metal material” include a structure where the first anchors 14 and the second anchors 33 are formed from the same composition of elements at the same composition ratio, and a structure where the first anchors 14 and the second anchors 33 are formed from the same composition of elements at different composition ratios. The second anchors 33 are embedded in the second multilayer wiring layer 32, and exposed from the surface (the surface facing away from the substrate 31) of the second multilayer wiring layer 32. The second anchors 33 are insulated from the control circuit disposed on the second chip 30. Specifically, the second anchors 33 are in the electrically floating state. The first anchors 14 are also insulated from the control circuit disposed on the second chip 30.

The first chip 10 is secured to the second chip 30 by connecting portions of the first anchors 14 exposed from the surface of the first insulating layer 11 and portions of the second anchors 33 exposed from the surface of the second multilayer wiring layer 32 with one another. The first anchors 14 and the second anchors 33 are connected by, for example, metal joining. The portions exposed from the surface of the first insulating layer 11 and the portions of the second anchors 33 exposed from the surface of the second multilayer wiring layer 32 do not have to completely match one another when the surface of the first insulating layer 11 is viewed in a plan. The portions may be arranged differently as long as at least a partial area of the portions exposed from the surface of the first insulating layer 11 and at least a partial area of the portions of the second anchors 33 exposed from the surface of the second multilayer wiring layer 32 are connected to one another. For example, the portions exposed from the surface of the first insulating layer 11 and the portions of the second anchors 33 exposed from the surface of the second multilayer wiring layer 32 may have the same size and be misaligned in the in-plane direction, or may have different sizes.

Multiple first bumps 51 protrude from the upper surface of the first chip 10, and multiple second bumps 52 protrude from a region in the upper surface of the second chip 30, not overlapping with the first chip 10. For example, Cu pillar bumps may be used as the first bumps 51 and the second bumps 52. The region of the upper surface of the first chip 10 where the first bumps 51 are not disposed, and the region of the upper surface of the second chip 30 where the second bumps 52 are not disposed are covered with an insulating protective film 50. The first bumps 51 are connected to a high-frequency circuit included in the first chip 10, and the second bumps 52 are connected to a control circuit included in the second chip 30. When the first bumps 51 and the second bumps 52 are connected to the land of the mounting board, a high-frequency circuit component is mounted on a mounting board.

FIG. 1B is a diagram of an arrangement of the first anchors 14 and the second anchors 33 in a plan view. Here, “in a plan view” indicates a case where “the upper surface of the substrate 31 is viewed in a plan. The first anchors 14 and the second anchors 33 are located slightly inward from the outer peripheral line of the first chip 10 in a plan view, discretely along a closed line aligning the outer peripheral line. As many first anchors 14 and second anchors 33 as required to fully secure the first chip 10 to the second chip 30 are provided.

FIG. 1C is a schematic cross-sectional view of an example of a connection portion between the first anchor 14 and the second anchor 33. The surface of the first insulating layer 11 in the first chip 10 and the end surface of the first anchor 14 are substantially flush with one another, and the surface of the second multilayer wiring layer 32 in the second chip 30 and the end surface of the second anchor 33 are substantially flush with one another. Thus, when the exposed portions of the first anchors 14 and the exposed portions of the second anchors 33 are connected, the first insulating layer 11 in the first chip 10 and the second multilayer wiring layer 32 in the second chip 30 come into contact with each other.

FIG. 1D is a schematic cross-sectional view of another example of a connection portion between the first anchor 14 and the second anchor 33. The end portion of the first anchor 14 protrudes from the surface of the first insulating layer 11 in the first chip 10. The tip of the protruding portion of the first anchor 14 is connected to the end surface of the second anchor 33. In this case, a small gap is left between the first insulating layer 11 in the first chip 10 and the second multilayer wiring layer 32 in the second chip 30.

In either the structure in FIG. 1C or the structure in FIG. 1D, the first anchor 14 and the second anchor 33 are joined together as a metal by bringing the first anchor 14 and the second anchor 33 into contact with each other and pressing the first anchor 14 and the second anchor 33 against each other. As illustrated in FIG. 1D, when the end portion of the first anchor 14 protrudes from the surface of the first insulating layer 11, the force with which the first chip 10 is pressed against the second chip 30 during joining is concentrated during the joining at contact portions between the first anchors 14 and the second anchors 33. Thus, the first anchor 14 and the second anchor 33 are easily joined together as a metal.

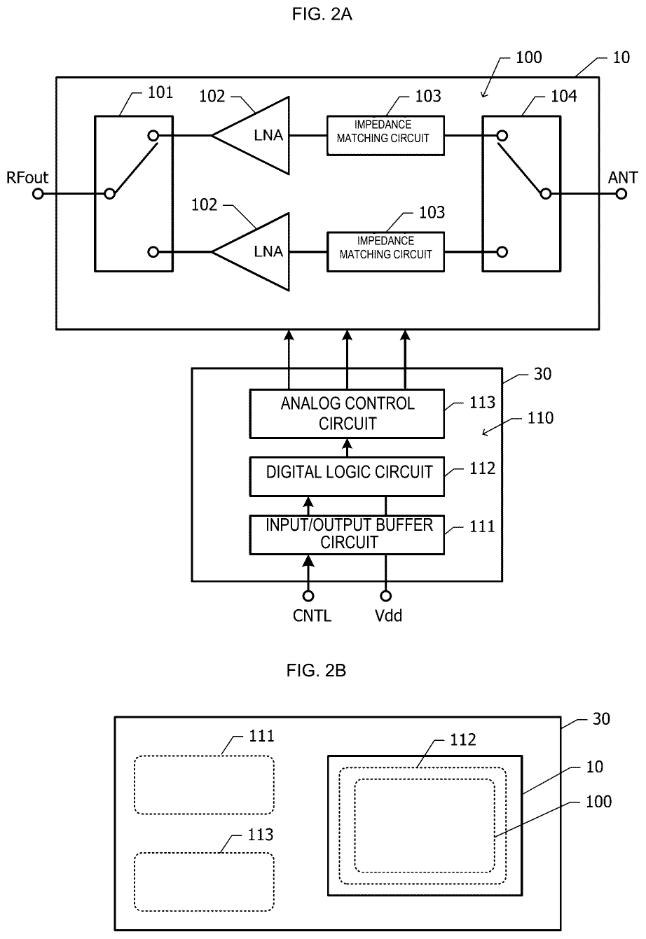

FIG. 2A is a block diagram of the high-frequency circuit component according to the first embodiment. A high-frequency circuit 100 including an output switch 101, two low-noise amplifiers 102, two impedance matching circuits 103, and an antenna switch 104 is disposed on the first chip 10. A control circuit 110 including an input/output buffer circuit 111, a digital logic circuit 112, and an analog control circuit 113 is disposed on the second chip 30.

The output switch 101, the low-noise amplifiers 102, and the antenna switch 104 are formed from, for example, the transistor 15 (FIG. 1A) and the multiple wires 13W and the vias 13V in the first multilayer wiring layer 13 (FIG. 1A). The impedance matching circuits 103 include a capacitor and an inductor formed from, for example, the wires 13W and the vias 13V in the first multilayer wiring layer 13. The input/output buffer circuit 111, the digital logic circuit 112, and the analog control circuit 113 are formed from the transistors 35 (FIG. 1A) and the multiple wires 32W and the vias 32V in the second multilayer wiring layer 32 (FIG. 1A).

Each of the output switch 101 and the antenna switch 104 is, for example, a single-pole double-throw (SPDT) switch. The output switch 101 connects an output node of one of the two low-noise amplifiers 102 to an output terminal RFout. The antenna switch 104 connects one antenna terminal ANT to one of the two impedance matching circuits 103. The two impedance matching circuits 103 are connected to the input nodes of the two low-noise amplifiers 102.

Power is supplied from a power supply terminal Vdd to the control circuit 110. A control signal is input into the input/output buffer circuit 111 from a control terminal CNTL. The digital logic circuit 112 decodes the control signal input into the input/output buffer circuit 111, and operates the analog control circuit 113. The analog control circuit 113 controls the operations of the output switch 101, the antenna switch 104, and the low-noise amplifiers 102 in the high-frequency circuit 100 in accordance with the control signal input from the control terminal CNTL.

The high-frequency signal input from the antenna terminal ANT is amplified through the impedance matching circuit 103 and the low-noise amplifier 102 selected by the antenna switch 104 and the output switch 101, and output from the output terminal RFout.

FIG. 2B is a diagram of a positional relationship between the high-frequency circuit 100, the input/output buffer circuit 111, the digital logic circuit 112, and the analog control circuit 113 in a plan view. The first chip 10 smaller than the second chip 30 is secured to the second chip 30. The input/output buffer circuit 111 and the analog control circuit 113 are disposed in a region not overlapping the first chip 10. The digital logic circuit 112 is disposed in a region overlapping the first chip 10.

Compared to the input/output buffer circuit 111 and the analog control circuit 113, the digital logic circuit 112 is less susceptible to electromagnetic noise produced from the high-frequency circuit 100. The digital logic circuit 112 less susceptible to electromagnetic noise is disposed in the region overlapping the first chip 10 on which the high-frequency circuit 100 is disposed, and the digital logic circuit 112 and the input/output buffer circuit 111 more susceptible to electromagnetic noise are disposed in the region not overlapping the first chip 10. The high-frequency circuit component can thus maintain electromagnetic compatibility (EMC).

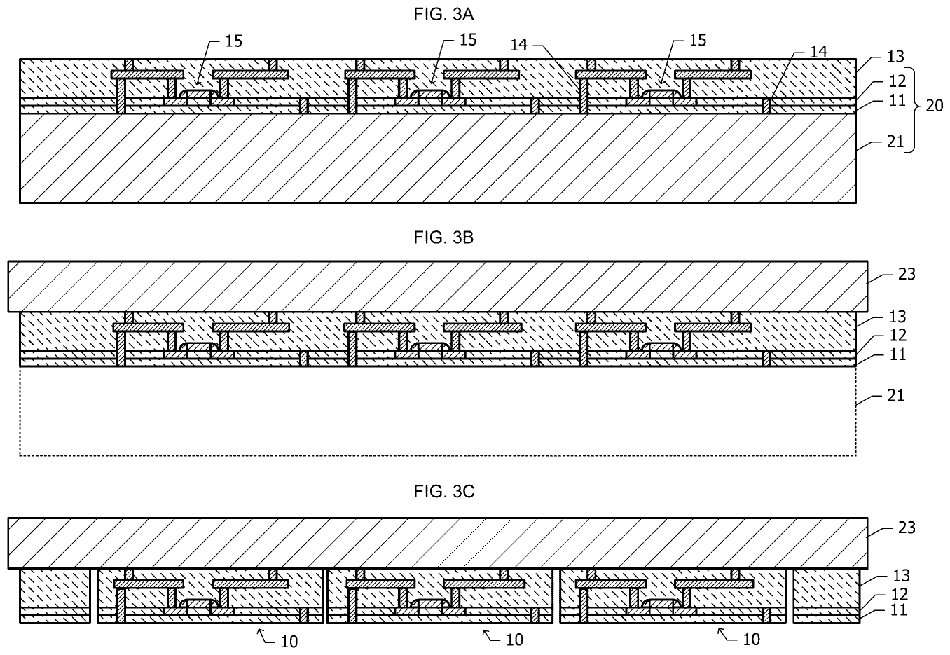

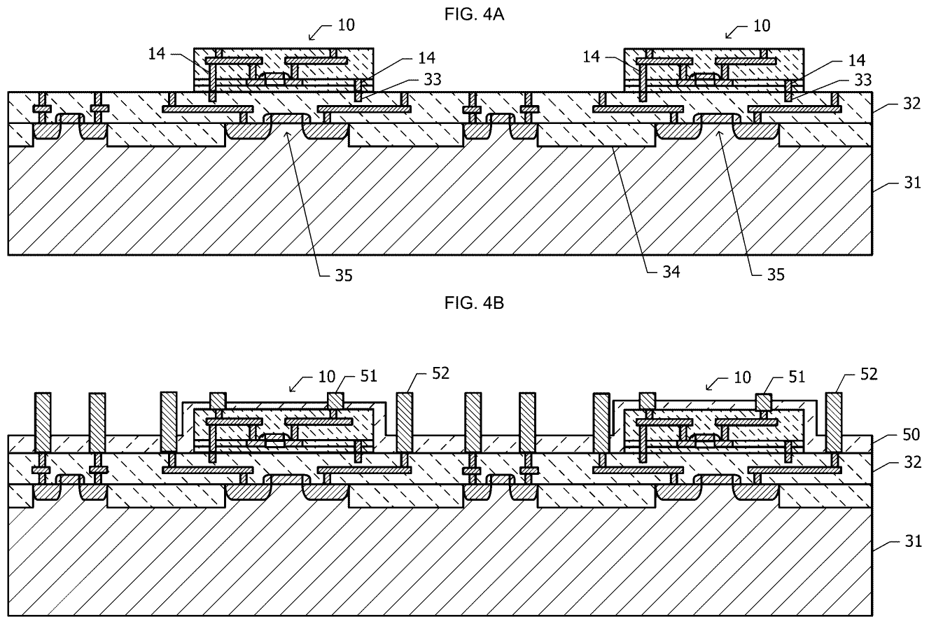

With reference to FIG. 3A to FIG. 4B, a method for manufacturing a high-frequency circuit component according to the first embodiment is described. FIG. 3A, FIG. 3B, and FIG. 3C and FIG. 4A and FIG. 4B are schematic cross-sectional views of the high-frequency circuit component according to the first embodiment in manufacturing process.

As illustrated in FIG. 3A, an SOI substrate 20 including a support board 21, the first insulating layer 11 (embedded oxide film), and the first device layer 12 (SOI layer) is prepared. On the SOI substrate 20, a device isolation structure, the multiple transistors 15, and the multiple first anchors 14 reaching the interface between the first insulating layer 11 and the support board 21 are formed. The first anchors 14 may extend from the interface between the first insulating layer 11 and the support board 21 to the top layer portion of the support board 21. The first multilayer wiring layer 13 is disposed on the SOI substrate 20.

As illustrated in FIG. 3B, a temporary substrate 23 is bonded to the surface of the first multilayer wiring layer 13, and the support board 21 is removed by grinding and abrading. In FIG. 3B, the removed support board 21 is drawn with a broken line. In a structure where the first anchors 14 extend to the top layer portion of the support board 21, the abrasion rate varies between the support board 21 and the first anchors 14. Thus, as illustrated in FIG. 1D, the tips of the first anchors 14 protrude from the surface of the first insulating layer 11.

As illustrated in FIG. 3C, the first insulating layer 11, the first device layer 12, and the first multilayer wiring layer 13 forming a laminated structure are cut with a dicing machine to divide the laminated structure into multiple first chips 10. The multiple first chips 10 are supported by the temporary substrate 23.

As illustrated in FIG. 4A, the element isolation regions 34 are formed in the top layer portion of the substrate 31 formed from, for example, silicon to define multiple active regions, and the transistors 35 are formed in the active regions and on the active regions. The second multilayer wiring layer 32 is further formed on the substrate 31. At this time, the multiple second anchors 33 embedded in the second multilayer wiring layer 32 are formed.

The first chip 10 is detached from the temporary substrate 23 (FIG. 3C), the first anchors 14 are brought into contact with the second anchors 33 and pressed against the second anchors 33 to secure the first chip 10 onto the second multilayer wiring layer 32.

As illustrated in FIG. 4B, the insulating protective film 50 covering the first chip 10 and the second multilayer wiring layer 32 is formed. Multiple openings are formed in the protective film 50, and the first bumps 51 and the second bumps 52 are formed in these openings. Thereafter, the substrate 31 and the second multilayer wiring layer 32 are cut with a dicing machine to obtain multiple high-frequency circuit components (FIG. 1A).

One or more preferable effects of the first embodiment are described now.

In the first embodiment, the first chip 10 including a high-frequency circuit is laminated on and secured to the second chip 30 including a control circuit that controls the high-frequency circuit. Thus, compared to a structure where a chip including a high-frequency circuit and a chip including a control circuit are separately mounted on a mounting board, the high-frequency circuit component can be reduced in size.

In the first embodiment, the first anchors 14 in the first chip 10 and the second anchors 33 in the second chip 30 are brought into contact with each other and pressed against each other to secure the first chip 10 to the second chip 30. Thus, the first chip 10 is secured to the second chip 30 without, for example, a polymer adhesive. The first anchors 14 and the second anchors 33 are formed from the same pure metal or the same alloy, and thus can be easily joined together as a metal. For example, copper, tungsten, aluminum, titanium, tantalum, or an alloy containing any of these metallic elements as a main content may be used for the first anchors 14 and the second anchors 33.

In the first embodiment, the first chip 10 is divided into pieces, and then the multiple first chips 10 are fixed to the second chip 30 not divided into pieces. Thus, after the multiple first chips 10 and the multiple second chips 30 are inspected for defects, the first chips 10 having no defect and the second chips 30 having no defect are combined to form high-frequency circuit components. Thus, the structure according to the first embodiment can have improved yield.

In the first embodiment, in the first chip 10 including the high-frequency circuit, the support board 21 (FIG. 3A) of the SOI substrate 20 is removed. Thus, a strain attributable to a parasitic capacitance between the support board 21 and the transistor 15 of the high-frequency circuit can be reduced. Thus, the high-frequency characteristics of the high-frequency circuit component can be improved. To more effectively improve the high-frequency characteristics of the high-frequency circuit component, an increase of the parasitic capacitance between the transistor 15 of the high-frequency circuit and the substrate 31 of the second chip 30 is desirably reduced. To reduce an increase of the parasitic capacitance, a distance in the thickness direction from the first insulating layer 11 in the first chip 10 to the substrate 31 is preferably greater than or equal to 10 μm.

In a semiconductor process using an SOI substrate, to prevent the silicon substrate from having a floating potential, a through-silicon via (substrate contact) extending through the embedded oxide film to the silicon substrate is formed. In the structure where the silicon substrate is finally removed, water may flow through the through-silicon via into a device located nearer the device layer. In the first embodiment, the second chip 30 to which the first chip 10 is secured blocks the path through which water flows, and thus the structure in the first embodiment can maintain waterproofness.

In the first embodiment, the first anchors 14 and the second anchors 33 are in the floating state. Thus, the second anchors 33 do not limit the design freedom of routing the wires 32W in the second multilayer wiring layer 32 (FIG. 1A).

A modification of the first embodiment is described now.

In the first embodiment, the high-frequency circuit 100 included in the first chip 10 includes the low-noise amplifiers 102 (FIG. 2A), but may additionally include a power amplifier. The power amplifier amplifies power of a transmission signal transmitted from an antenna.

### Second Embodiment

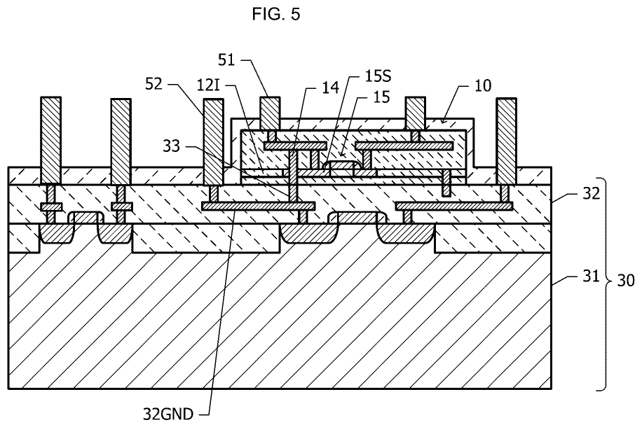

Subsequently, a high-frequency circuit component according to a second embodiment is described with reference to FIG. 5. Components the same as the components in the high-frequency circuit component according to the first embodiment described with reference to FIG. 1A to FIG. 4B are not described below.

FIG. 5 is a schematic cross-sectional view of a high-frequency circuit component according to a second embodiment. In the high-frequency circuit component according to the first embodiment, the first anchors 14 are embedded in the element isolation region 12I of the first device layer 12. In contrast, in the second embodiment, the first anchors 14 are disposed in a source region 15S of the transistor 15, and electrically connected to the source region 15S. The source region 15S has a ground potential. The second anchors 33 are electrically connected to the ground wires 32GND in the second multilayer wiring layer 32 in the second chip 30. Thus, the source region 15S of the transistor 15 is connected to the ground wires 32GND with the first anchors 14 and the second anchors 33 interposed therebetween. The ground wires 32GND is connected to a ground conductor of the mounting board with the second bumps 52 interposed therebetween.

One or more preferable effects of the second embodiment are described now.

The structure according to the second embodiment, as in the structure according to the first embodiment, successfully improves the high-frequency characteristics and enhances the yield. In addition, in the structure according to the second embodiment, the first anchors 14 and the second anchors 33 that secure the first chip 10 to the second chip 30 electrically connect the region of the first chip 10 that is to have a ground potential, to the ground potential of the second chip 30. Thus, the first anchors 14 and the second anchors 33 that mechanically connect the first chip 10 to the second chip 30 are also used as electrical connection paths.

In the process of manufacturing the first chip 10, the first anchors 14 can be used as substrate contacts that fix the potential of the support board 21 (FIG. 3A) formed from silicon. This structure eliminates the need of providing another substrate contact separately from the first anchors 14.

The ground wires 32GND and the second bumps 52 function as heat dissipation paths from the second chip 30 to the ground conductor of the mounting board. Heat generated at the transistor 15 of the first chip 10 is dissipated to the mounting board through the first bumps 51 and the wires 13W in the first multilayer wiring layer 13. In addition to the heat dissipation paths, the first anchors 14, the second anchors 33, the ground wires 32GND, and the second bumps 52 also function as heat dissipation paths that dissipate heat generated at the transistors 35 of the first chip 10 to the mounting board. Thus, the structure has an effect of improving dissipation of heat from the first chip 10.

### Third Embodiment

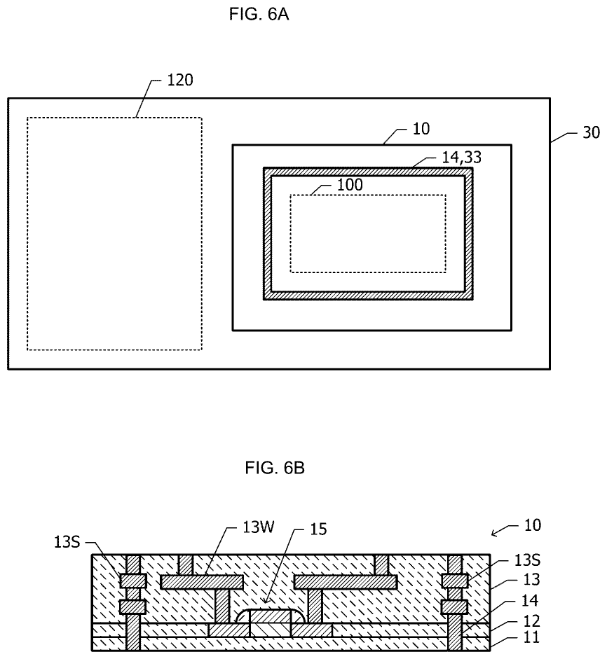

A high-frequency circuit component according to a third embodiment is described now with reference to FIG. 6A and FIG. 6B. Components the same as the components in the high-frequency circuit component according to the first embodiment described with reference to FIG. 1A to FIG. 4B are not described below.

FIG. 6A is a diagram of a positional relationship between the first chip 10, the second chip 30, the first anchors 14, and the second anchors 33 in a high-frequency circuit component according to a third embodiment in a plan view, and FIG. 6B is a schematic cross-sectional view of the first chip 10. In the first embodiment (FIG. 1A and FIG. 1B), the prism-shaped first anchors 14 and second anchors 33 are discretely arranged slightly inward from the outer peripheral line of the first chip 10 in a plan view. In contrast, in the third embodiment, the first anchors 14 and the second anchors 33 are disposed to continuously surround the high-frequency circuit 100 (FIG. 2A) included in the first chip 10 in a plan view.

As illustrated in FIG. 6B, shield rings 13S are disposed in the first multilayer wiring layer 13 to surround the high-frequency circuit 100 in a plan view. The shield rings 13S are vias that connect wires in multiple layers in the first multilayer wiring layer 13 to each other, and connect wire layers to each other. The shield rings 13S are connected to the first anchors 14. The shield rings 13S are connected to the ground potential.

One or more preferable effects of the third embodiment are described now.

The structure according to the third embodiment, as in the structure according to the first embodiment, successfully improves the high-frequency characteristics and enhances the yield. In addition, in the structure according to the third embodiment, the first anchors 14 have an electromagnetic shielding function together with the shield ring 13S, and thus can enhance electromagnetic compatibility (EMC).

### Fourth Embodiment

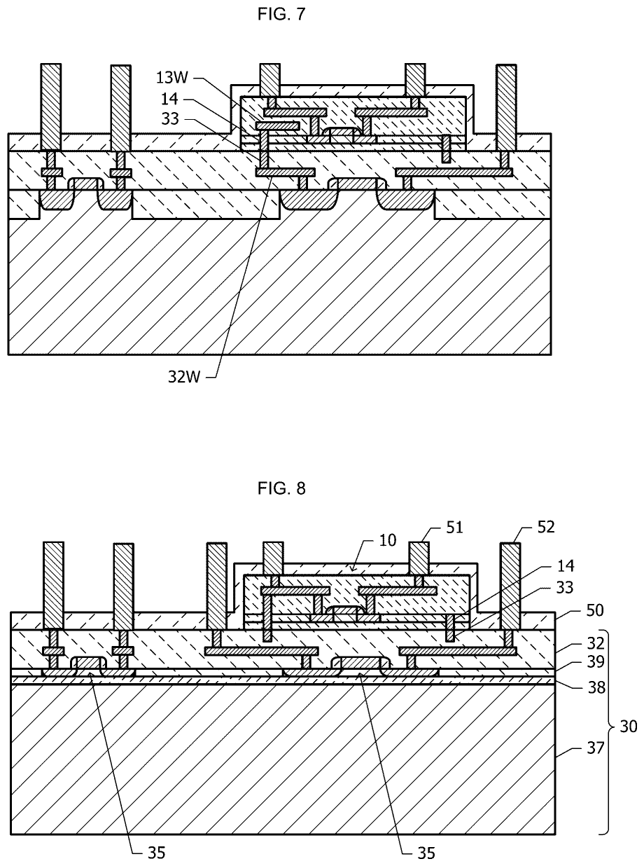

A high-frequency circuit component according to a fourth embodiment is described now with reference to FIG. 7. Components the same as the components in the high-frequency circuit component according to the first embodiment described with reference to FIG. 1A to FIG. 4B are not described below.

FIG. 7 is a schematic cross-sectional view of a high-frequency circuit component according to a fourth embodiment. In the first embodiment (FIG. 1A), the first anchors 14 and the second anchors 33 are in the electrically floating state. In contrast, in the fourth embodiment, the first anchors 14 are connected to the high-frequency circuit 100 (FIG. 2A) in the first chip 10, and the second anchors 33 are connected to the control circuit 110 (FIG. 2A) in the second chip 30. Thus, the high-frequency circuit 100 in the first chip 10 and the control circuit 110 in the second chip 30 are connected to each other with the first anchors 14 and the second anchors 33 interposed therebetween.

For example, the analog control circuit 113, the low-noise amplifiers 102, the output switch 101, and the antenna switch 104 illustrated in FIG. 2A are connected using the first anchors 14 and the second anchors 33.

One or more preferable effects of the fourth embodiment are described now.

The structure according to the fourth embodiment, as in the structure according to the first embodiment, successfully improves the high-frequency characteristics and enhances the yield. In addition, in the structure according to the fourth embodiment, the first anchors 14 and the second anchors 33 electrically connect the high-frequency circuit 100 in the first chip 10 and the control circuit 110 in the second chip 30 to each other. Thus, this structure has no need of providing wires outside to connect the high-frequency circuit 100 and the control circuit 110 to each other.

### Fifth Embodiment

A high-frequency circuit component according to a fifth embodiment is described now with reference to FIG. 8. Components the same as the components in the high-frequency circuit component according to the first embodiment described with reference to FIG. 1A to FIG. 4B are not described below.

FIG. 8 is a schematic cross-sectional view of a high-frequency circuit component according to a fifth embodiment. In the first embodiment (FIG. 1A), the substrate 31 included in the second chip 30 is a bulk silicon substrate. In contrast, in the fifth embodiment, the second chip 30 includes an SOI substrate. The SOI substrate includes a support board 37 formed from silicon, an embedded oxide film 38, and a second device layer 39. The source region and the drain region of each transistor 35 are formed in the second device layer 39. In the first chip 10, as illustrated in FIG. 3B, the support board 21 of the SOI substrate 20 is removed. In the second chip 30, the support board 37 is used as a substrate that mechanically supports the first chip 10 instead of being removed.

One or more preferable effects of the fifth embodiment are described now.

The structure according to the fifth embodiment, as in the structure according to the first embodiment, successfully improves the high-frequency characteristics and enhances the yield. In addition, in the structure according to the fifth embodiment, the second chip 30 including an SOI substrate can improve the operation speed of the control circuit formed in the second chip 30.

### Sixth Embodiment

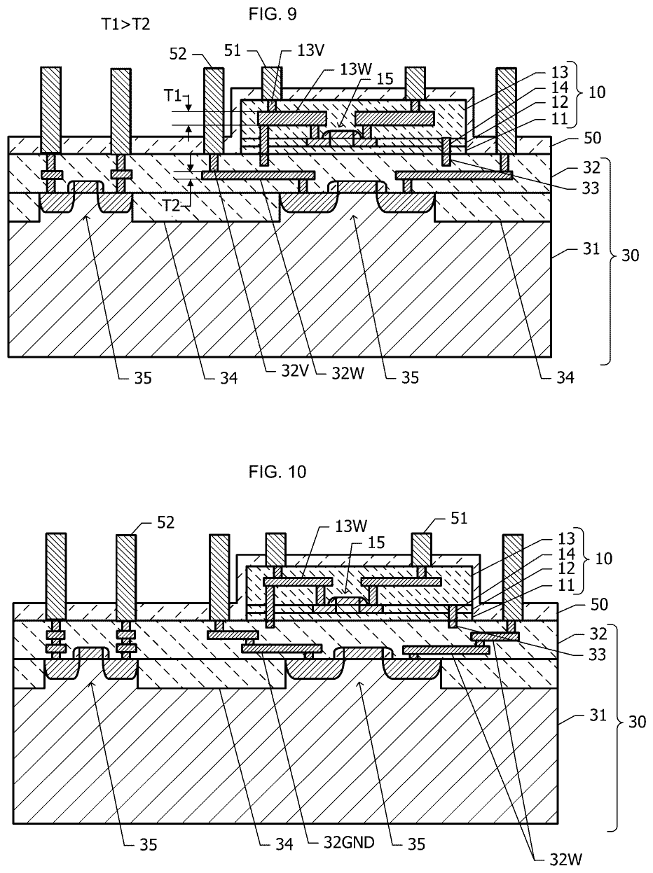

A high-frequency circuit component according to a sixth embodiment is described now with reference to FIG. 9. Components the same as the components in the high-frequency circuit component according to the first embodiment described with reference to FIG. 1A to FIG. 4B are not described below.

FIG. 9 is a schematic cross-sectional view of a high-frequency circuit component according to a sixth embodiment. In the first embodiment (FIG. 1A), the film thickness of the wires 13W in the first multilayer wiring layer 13 in the first chip 10 and the wires 32W in the second multilayer wiring layer 32 in the second chip 30 are not particularly described. In the high-frequency circuit component according to the sixth embodiment, a film thickness T1 of the wires 13W in the first multilayer wiring layer 13 in the first chip 10 is greater than a film thickness T2 of the wires 32W in the second multilayer wiring layer 32 in the second chip 30.

Heat generated at the transistor 15 disposed on the first chip 10 is dissipated to the mounting board mainly through the wires 13W and the vias 13V in the first multilayer wiring layer 13 and the first bumps 51. Heat generated at the transistors 35 disposed on the second chip 30 is dissipated to the mounting board mainly through the wires 32W and the vias 32V in the second multilayer wiring layer 32 and the second bumps 52. Heat generated at the multiple transistors 15 forming the low-noise amplifiers 102 (FIG. 2A) in the high-frequency circuit 100 is more than heat generated at the transistors 35 disposed on the second chip 30 forming the control circuit 110 (FIG. 2A).

The structure according to the sixth embodiment, as in the structure according to the first embodiment, successfully improves the high-frequency characteristics and enhances the yield. In addition, in the structure according to the sixth embodiment, the wires 13W in the first multilayer wiring layer 13 used as heat dissipation paths from the transistor 15 have a relatively large film thickness, and thus successfully improves heat dissipation from the transistors 15 that generate relatively more heat. The wires 32W in the second multilayer wiring layer 32 have a relatively smaller film thickness, and thus successfully simplifies the process of forming wires including, for example, damascene. When each of the first multilayer wiring layer 13 and the second multilayer wiring layer 32 includes multiple wire layers, preferably, the sum of the film thicknesses Tl of the wire layers in the first multilayer wiring layer 13 is greater than the sum of the film thicknesses T2 of the wire layers in the second multilayer wiring layer 32.

### Seventh Embodiment

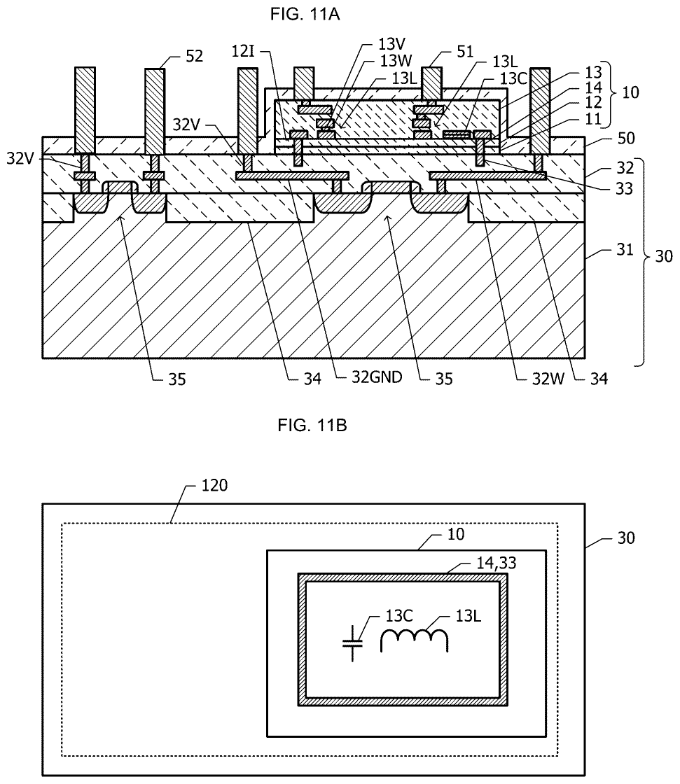

A high-frequency circuit component according to a seventh embodiment is described now with reference to FIG. 10. Components the same as the components in the high-frequency circuit component according to the first embodiment described with reference to FIG. 1A to FIG. 4B are not described below.

FIG. 10 is a schematic cross-sectional view of a high-frequency circuit component according to a seventh embodiment. In the first embodiment (FIG. 1A), the number of wire layers in the first multilayer wiring layer 13 in the first chip 10 and the number of wire layers in the second multilayer wiring layer 32 in the second chip 30 are not particularly described. In the high-frequency circuit component according to the seventh embodiment, the second multilayer wiring layer 32 in the second chip 30 includes more wire layers than the first multilayer wiring layer 13 in the first chip 10. In the example illustrated in FIG. 10, the first multilayer wiring layer 13 includes one wire layer, and the second multilayer wiring layer 32 includes two wire layers, but the number of wire layers is not limited to this case. For example, the first multilayer wiring layer 13 may include two wire layers, and the second multilayer wiring layer 32 may include three or more wire layers.

One or more preferable effects of the seventh embodiment are described now.

The structure according to the seventh embodiment, as in the structure according to the first embodiment, successfully improves the high-frequency characteristics and enhances the yield. In addition, in the structure according to the seventh embodiment, the first multilayer wiring layer 13 includes fewer wire layers, and thus successfully enhances the heat dissipation from the transistor 15 disposed on the first chip 10 to the mounting board through the wires 13W, the vias 13V, and the first bumps 51. When the second multilayer wiring layer 32 includes more wire layers, the freedom of layout of the wires 32W can be enhanced.

### Eighth Embodiment

A high-frequency circuit component according to an eighth embodiment is described now with reference to FIG. 11A and FIG. 11B. Components the same as the components in the high-frequency circuit component according to the first embodiment described with reference to FIG. 1A to FIG. 4B are not described below.

FIG. 11A is a schematic cross-sectional view of a high-frequency circuit component according to an eighth embodiment, and FIG. 11B is a diagram of a positional relationship among various components in a high-frequency circuit component in a plan view. In the first embodiment (FIG. 1A and FIG. 2A), the high-frequency circuit 100 including components such as the low-noise amplifiers 102 are disposed on the first chip 10. In contrast, in the eighth embodiment, the first chip 10 is an integrated passive device (IPD), and for example, a filter circuit including a capacitor 13C and an inductor 13L is disposed on the first chip 10.

As in the first embodiment (FIG. 1A), the first chip 10 includes the first insulating layer 11, the first device layer 12, the first multilayer wiring layer 13, and the first anchors 14. The first device layer 12 is insulated, and the capacitor 13C is disposed on the first device layer 12. The inductor 13L is formed from the wires 13W and the vias 13V in the first multilayer wiring layer 13.

The first anchors 14 and the second anchors 33 (FIG. 11B) are arranged to continuously surround the capacitor 13C and the inductor 13L in a plan view. The multiple transistors 35 are disposed on the second chip 30, and the control circuit 110 includes components such as the multiple transistors 35.

One or more preferable effects of the eighth embodiment are described now.

In the eighth embodiment, the first chip 10, which is an integrated passive device, is laminated on and secured to the second chip 30 on which the control circuit 110 is disposed. Thus, the high-frequency circuit component including the integrated passive device and a control circuit has a reduced size.

The above-described embodiments are mere examples, and it is needless to say that components between different embodiments may partially be replaced or combined. The same components in the multiple embodiments having the same effects are not described one by one. The present disclosure is not limited to the above embodiments. It will be apparent to those skilled in the art that the above embodiments may be, for example, changed, modified, and combined in various manners.

Based on the above embodiments described herein, the following disclosure is disclosed.
<1> A high-frequency circuit component, comprising a first chip that includes a first insulating layer, a first device layer laminated on the first insulating layer, a first multilayer wiring layer laminated on the first device layer, and a first anchor to form a high-frequency circuit; and a second chip that includes a substrate, a second multilayer wiring layer disposed on the substrate, and a second anchor to form a control circuit that controls the high-frequency circuit. The first anchor is embedded in the first device layer and the first insulating layer, and exposed from a surface of the first insulating layer. The second anchor is embedded in the second multilayer wiring layer, and exposed from a surface of the second multilayer wiring layer. The first anchor and the second anchor are formed from an identical metal material, and a portion of the first anchor exposed from the surface of the first insulating layer and a portion of the second anchor exposed from the surface of the second multilayer wiring layer are connected to each other.
<2> The high-frequency circuit component according to <1>, wherein a sum of film thicknesses of a plurality of wires in the first multilayer wiring layer is greater than a sum of film thicknesses of a plurality of wires in the second multilayer wiring layer.
<3> The high-frequency circuit component according to <1>or <2>, wherein the first anchor is connected to a region in the first device layer having a ground potential, the second multilayer wiring layer includes a ground wire, and the second anchor is connected to the ground wire.
<4> The high-frequency circuit component according to <1>or <2>, wherein the first anchor is connected to the high-frequency circuit, and the second anchor is connected to the control circuit.
<5> The high-frequency circuit component according to any one of <1>to <4>, wherein the second multilayer wiring layer includes more layers than the first multilayer wiring layer.
<6> The high-frequency circuit component according to any one of <1>to <5>, wherein when the substrate is viewed in a plan, the second chip expands outward beyond the first chip. Also, the high-frequency circuit component further comprises a first bump protruding from the first multilayer wiring layer, and a second bump protruding from a portion of the second multilayer wiring layer that does not overlap the first chip when viewed in a plan. In addition, the second anchor is connected to the second bump with a wire in the second multilayer wiring layer.
<7> The high-frequency circuit component according to <1>or <2>, wherein the first anchor and the second anchor are insulated from the control circuit.

What is claimed is:

1. A high-frequency circuit component, comprising:
a first chip that includes a first insulating layer, a first device layer laminated on the first insulating layer, a first multilayer wiring layer laminated on the first device layer, and a first anchor configured as a high-frequency circuit; and
a second chip that includes a substrate, a second multilayer wiring layer on the substrate, and a second anchor configured as a control circuit that controls the high-frequency circuit,
wherein
the first anchor is embedded in the first device layer and the first insulating layer, and exposed from a surface of the first insulating layer,
the second anchor is embedded in the second multilayer wiring layer, and exposed from a surface of the second multilayer wiring layer, and
the first anchor and the second anchor include an identical metal material, and a portion of the first anchor exposed from the surface of the first insulating layer and a portion of the second anchor exposed from the surface of the second multilayer wiring layer are connected to each other.

2. The high-frequency circuit component according to claim 1, wherein
a sum of film thicknesses of a plurality of wires in the first multilayer wiring layer is greater than a sum of film thicknesses of a plurality of wires in the second multilayer wiring layer.

3. The high-frequency circuit component according to claim 1, wherein
the first anchor is connected to a region in the first device layer having a ground potential,
the second multilayer wiring layer includes a ground wire, and
the second anchor is connected to the ground wire.

4. The high-frequency circuit component according to claim 1, wherein
the first anchor is connected to the high-frequency circuit, and the second anchor is connected to the control circuit.

5. The high-frequency circuit component according to claim 1, wherein
the second multilayer wiring layer includes more layers than the first multilayer wiring layer.

6. The high-frequency circuit component according to claim 1, wherein
when the substrate is viewed in a plan, the second chip expands outward beyond the first chip,
the high-frequency circuit component further comprises
a first bump protruding from the first multilayer wiring layer, and
a second bump protruding from a portion of the second multilayer wiring layer that does not overlap the first chip when viewed in a plan, and
the second anchor is connected to the second bump with a wire in the second multilayer wiring layer.

7. The high-frequency circuit component according to claim 1, wherein
the first anchor and the second anchor are insulated from the control circuit.

8. The high-frequency circuit component according to claim 2, wherein
the first anchor is connected to a region in the first device layer having a ground potential,
the second multilayer wiring layer includes a ground wire, and
the second anchor is connected to the ground wire.

9. The high-frequency circuit component according to claim 2, wherein
the first anchor is connected to the high-frequency circuit, and the second anchor is connected to the control circuit.

10. The high-frequency circuit component according to claim 2, wherein
the second multilayer wiring layer includes more layers than the first multilayer wiring layer.

11. The high-frequency circuit component according to claim 2, wherein
when the substrate is viewed in a plan, the second chip expands outward beyond the first chip,
the high-frequency circuit component further comprises
a first bump protruding from the first multilayer wiring layer, and
a second bump protruding from a portion of the second multilayer wiring layer that does not overlap the first chip when viewed in a plan, and
the second anchor is connected to the second bump with a wire in the second multilayer wiring layer.

12. The high-frequency circuit component according to claim 2, wherein
the first anchor and the second anchor are insulated from the control circuit.
